(19) United States
(12) Patent Application Publication
(10) Pub. No.: US 2006/0121192 A1
(43) Pub. Date: Jun. 8, 2006

(54) Liquid precursor refill system

(76) Inventors: Benjamin J. Jurcik, Richardson, TX (US); Jean-Marc Girard, Paris (FR); Guillaume Rameau, Grenoble (FR)

Correspondence Address: AIR LIQUIDE, 2700 POST OAK BOULEVARD, SUITE 1800, HOUSTON, TX, 77056, US

(21) Appl. No.: 11/095,792

(22) Filed: Mar. 31, 2005

Related U.S. Application Data
(60) Provisional application No. 60/632,711, filed on Dec. 2, 2004.

(51) Int. Cl. C23C 16/00

(52) U.S. Cl. 427/248.1; 118/715

(57) ABSTRACT

Liquid precursor refill systems of the type typically used in the semiconductor industry. A remote precursor reservoir and a secondary vapor delivery system provide a CVD precursor to a local source. The local source contains a heat transfer means and a local CVD precursor reservoir. A delivery line connects this remote, secondary vapor delivery system and the local heat transfer means. During the constant or periodic operation, no liquid is present in the delivery line. The local CVD precursor reservoir may serve as an ampoule in a bubbler system, or may provide CVD precursor to an ampoule in a bubbler system.

### CROSS-REFERENCE TO RELATED APPLICATIONS

This application claims the benefit of U.S. Provisional Application No. 60/632,711, filed Dec. 2, 2004, the entire contents of which are incorporated herein by reference.

### BACKGROUND

The semiconductor industry is very dependent upon sources of ultrahigh purity reagents. Other industries also have high purity requirements, but few compare with the purity requirements in the semiconductor industry. Chemical vapor deposition (CVD) systems are used in a number of manufacturing processes in the semiconductor industry as well as many other industries. For example, chemical vapor deposition systems are used in the manufacture of optical wave-guides. Thin films are also sometimes produced by vapor deposition system technology.

In the electronics industry, many materials that are used as CVD precursors are liquids at room temperature and atmospheric pressure. That is to say that the vapor pressure of the material is less than atmospheric pressure at temperatures in the-range of 15° C.-35° C. In order to use these materials in the CVD process is it necessary to vaporize the materials by some fashion and introduce the vapors into the process chamber where the CVD process occurs. There are two processes that are currently widely used in the semiconductor industry, bubbling and vaporization. A bubbler uses a carrier gas (frequently nitrogen, helium, or argon) that is introduced by bubbling into a quantity of the liquid precursor material. The bubbles rise to the surface of the liquid due to the effects of gravity and the carrier leaves the bubbler. Due to the vapor pressure of the precursor material, a certain amount of material is carried over with the carrier gas. The carry over is due to the carrier gas becoming saturated with the precursor material vapor as it leaves the bubbler. The bubbler technique is most useful for those precursors that have a substantial vapor pressure. The second technique that is used is a vaporizer. A vaporizer is fed with a liquid feed stream and then converted into a vapor/carrier gas stream via atomization or nebulization. The vaporizer technique is most frequently used for precursors with very low vapor pressure.

Traditionally, in this industry, these precursors are provided in ampoules. Ampoules are in general small containers that can contain the precursor material and are made of a variety of materials. They may be configured to either deliver a liquid to the vaporizer or as a bubbler where the carrier gas is bubbled into the liquid. Ampoules may be typically made of quartz with a stem which can be broken off or alternatively in stainless steel or other high quality non-contaminating metal alloy. The ampoule is shipped from the manufacturer of the precursor material to the semiconductor producer. The ampoule is changed periodically as the material is utilized in order to maintain an adequate reservoir of precursor material. Typically, these ampoules of material are located very close to the CVD process chamber and the total volume of the ampoule is relatively small (maximum of several liters). Due to the proximity of the ampoule to the CVD process chamber, the ampoules are located in the clean room of the semiconductor fabrication facility.

Irrespective of the type of vapor delivery method that is used, a liquid capacity of precursor material is required near to the CVD chamber inlet. The precursor is fed by either vaporization technique into the CVD chamber. Practical design considerations limit the liquid volume amount of the precursor that can be stored near to the CVD chamber inlet. As a result, the liquid capacity must be either changed out on a periodic basis or refilled. The ampoule change is a long and cumbersome process and as the tool is typically located inside of a clean room it is not very practical to perform the ampoule changes inside of the clean room. The length of time for the ampoule change process is due to the fact that the entire manifold of material handling components must be diligently purged of all residual materials before the connection between the ampoule and the manifold can be open. The purging process is necessary for both safety and purity/contamination of the manifold.

In addition, the physical handling of bubblers filled with these reagents, which tend to be highly poisonous and very reactive, presents a certain safety problem. While with adequate care and suitable safety precautions the processes are carried out with a very high degree of safety, there is some risk always present.

Commercially available systems, such as Air Liquide's Candi system or EpiChem's EpiFill system, are liquid precursor delivery systems that are designed to automatically refill the liquid capacity that is located at the tool. These systems eliminate the need for ampoule changes within the clean room and also eliminate the associated down time that would normally be associated with an ampoule change. These systems work by providing a liquid delivery of the chemical precursor and by establishing a communication between the tool and the liquid precursor delivery system opens and closes the supply valves as needed. When the ampoule at the tool requires refilling, a signal is sent to the liquid precursor delivery system and the tool opens the ampoule supply valve. The liquid precursor delivery system then opens its supply valve and liquid precursor is pushed into the ampoule at the tool until it is refilled. The valves are shut when the ampoule has been filled. The advantages of these liquid precursor delivery systems for liquid precursor refilling systems are that equipment down time for chemical supply is eliminated, larger source canisters of precursor materials can be used leading to substantial cost savings, and significant labor savings as the number of the containers changes that are required at the site is reduced significantly.

The inherent benefits of these systems have led to a good commercial success of these products. As is evident from the process description above, the piping that connects these systems with the process tool (and the associated ampoule that is refilled) remains filled with the liquid precursor both during the refill operation and during the idle time when no refilling is occurring. For certain chemicals that have special highly reactive characteristics the storage of the liquid in the line poses some problems from a safety and permitting perspective.

As the distance from the system to the tool may be significant (250-500 feet or more), the amount of material stored in the line can be large. Materials that are pyrophoric and/or water reactive are most susceptible to these problems as there are strict rules governing the amount of material that maybe on a given site. In addition, having the pyrophoric liquid material stored in the line may be a safety concern as during other modifications, installations, etc., a contractor or worker might inadvertently cut into the liquid pyrophoric line. As there would be a substantial amount of material stored in that line, the resulting fire could be troublesome for the site. For trimethylaluminum, which is both pyrophoric and water reactive, the problem is compounded as with a breach in the line and resulting fire: the initiation of the sprinkler system would make the fire/explosion hazard even worse.

The obvious solution to the problem associated with liquid stored in the line is to not keep liquid in the line and refill and empty the line each time that the ampoule needs to be refilled. A difficulty with this approach is that a “push back” of liquid into the source container would not be acceptable because of the potential contamination of material. The EpiFill system operates in this fashion.

The alternative solution of sending to waste the material that is in the line would be too expensive as the liquid CVD precursor materials are very expensive, sometimes costing more than $50/gram.

Therefore, due to the various short comings in current methodologies to address these issues, there is a need in the industry to develop a more economical and safe solution.

### SUMMARY

This invention relates to liquid precursor refill systems of the type typically used in the semiconductor industry and, more particularly, to a system for refilling ampoules whereby the transfer line connecting the liquid source and the ampoule is primarily filled with vapor.

The present invention is designed to reduce the risk, and thereby, improve the efficiency of the refill process and reduce the reject rate, as well as improve the quality of the product. These and other objects are accomplished by providing a system that eliminates the need to replace the bubbler, or to manually refill it. The bubbler is automatically maintained between a minimum and a maximum level providing all the benefits of the existing liquid precursor delivery systems without having any liquid in the line connecting the delivery system and the tool. All of this is accomplished from a refill reservoir using unique and significant process steps and apparatus to prevent contamination and to assure safety. Thus, it is one of the facets of this invention to provide a system for automatically refilling bubblers, or the like, which are used as vapor delivery systems, without maintaining a quantity of liquid precursor in the delivery line in between fillings.

The present invention also provides the benefit in that the line between the remote precursor reservoir and the ampoule at the tool is never filled with liquid. A bubbler or vaporizer is utilized at the remote precursor reservoir cabinet and this vapor/carrier gas mixture is transported to the tool. A heat transfer means liquefies, or solidifies, the CVD precursor in the ampoule at the tool and provides the material as normally fed to the process tool. An additional benefit of this approach is that the bubbling system can provide a single stage of fractional distillation and improve the purity of the material that is actually delivered to the process chamber.

Another benefit of this approach is that the CVD precursor is condensed locally, and can be distributed to the end user in tiny quantities for spiking applications. The technique of spiking is used by some semiconductor fabrication facilities in order to keep a very constant mass of precursors in the ampoule or bubbler during all of the processes and not allow the liquid level to vary substantially. Maintaining a constant liquid level in the ampoule or bubbler maintains the thermal mass of the liquid in the delivery systems so that temperature changes that occur due to the vaporization process are reduced over time. The described system can answer requests for small amounts of liquid CVD precursor with a much faster response time.

One aspect of the present invention includes a method for providing CVD precursor to a primary vapor delivery system. The delivery method of the present invention includes maintaining a supply of a liquid phase CVD precursor in a remote precursor reservoir. This liquid CVD precursor is then passed through a vaporizing means, thus producing a vapor phase CVD precursor. This vapor phase CVD precursor is then periodically transferred, by way of a delivery line, to a heat transfer means. This vapor phase CVD precursor is then passed through the heat transfer means, thus producing either a liquid phase, or solid phase, CVD precursor. If it is a solid phase CVD precursor, the heat transfer means is subsequently used to change the CVD precursor to liquid phase. This liquid phase CVD precursor is then transferred to a local precursor reservoir. The delivery line pressure is maintained by way of constant vapor between these periodic transfers of vapor phase CVD precursor.

Another aspect of the present invention includes a system for providing CVD precursor to a primary vapor delivery system. The system of the present invention includes a CVD precursor remote source. This CVD precursor remote source includes a remote precursor reservoir and a secondary vapor delivery system. The system of the present invention also includes a CVD precursor local source. This CVD precursor local source includes a heat transfer means and a local precursor reservoir. A delivery line is included that connects the secondary vapor delivery system to the heat transfer means.

### BRIEF DESCRIPTION OF THE DRAWINGS

The invention may be understood by reference to the following description taken in conjunction with the accompanying drawings, and in which:

FIG. 1 is a stylized diagram of an illustrative embodiment of the invention; and

FIG. 2 is a stylized diagram of an illustrative embodiment of the invention indicating a multiple train operation.

### DESCRIPTION OF PREFERRED EMBODIMENTS

In one embodiment of the present invention, a method for providing CVD precursor to a primary vapor delivery system is provided. The delivery method of the present invention includes maintaining a supply of a liquid phase CVD precursor in a remote precursor reservoir. This liquid CVD precursor is then passed through a vaporizing means, thus producing a vapor phase CVD precursor. The vapor phase CVD precursor will most often be a mixture of the CVD precursor with a vaporization gas such as N₂, Ar, or He. This vapor phase CVD precursor is then periodically transferred, by way of a delivery line, to a heat transfer means, which is typically located near the primary vapor delivery means of the CVD tool. This vapor phase CVD precursor is then passed through the heat transfer means, thus producing a liquid phase CVD precursor. This liquid phase CVD precursor is then transferred to a local precursor reservoir. The delivery line pressure is maintained by way of constant vapor pressure between these periodic transfers of vapor phase CVD precursor.

In another embodiment of the present invention, a system for providing CVD precursor to a primary vapor delivery system is provided. The system of the present invention includes a CVD precursor remote source. This CVD precursor remote source includes a remote precursor reservoir and a secondary vapor delivery system. The system of the present invention also includes a CVD precursor local source. This CVD precursor local source includes a heat transfer means and a local precursor reservoir. A delivery line is included that connects the secondary vapor delivery system to the heat transfer means.

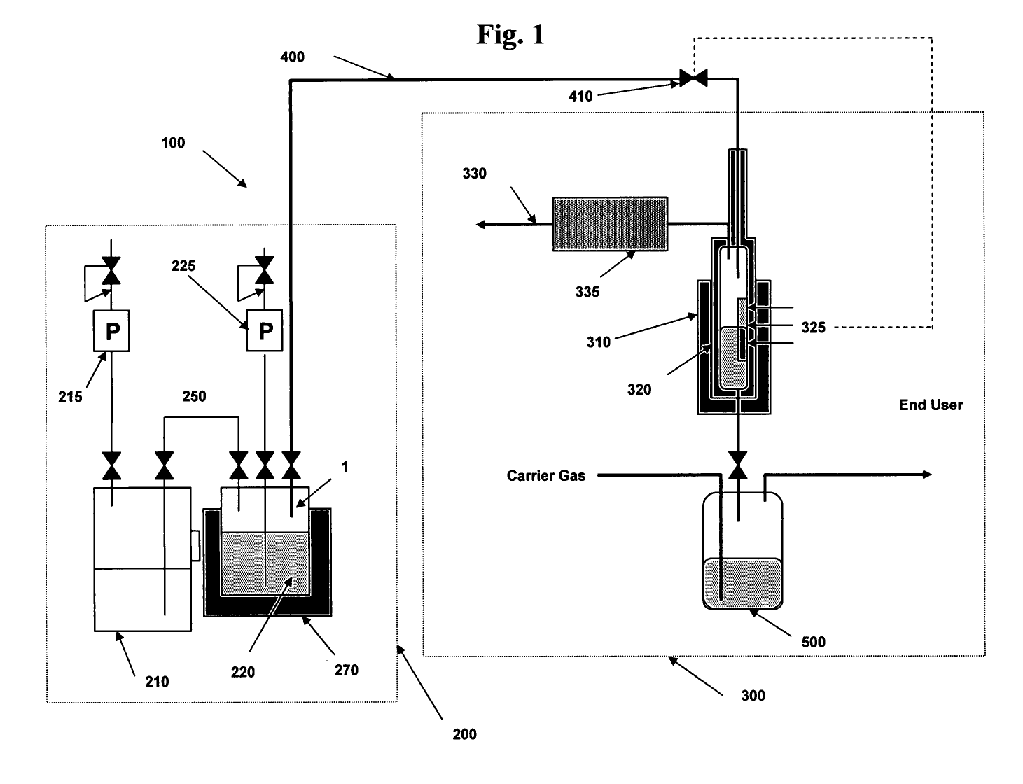

FIG. 1 depicts an illustrative embodiment of a CVD precursor delivery system 100 according to the present invention. The CVD precursor delivery system 100 includes a secondary system 200 and a primary system 300. The secondary system 200 includes a remote precursor reservoir 210 and a secondary vapor delivery system 220. The primary system 300 includes a heat transfer means 310 and a local precursor reservoir 320. The secondary system 200 is in fluid communication with the primary system 300 by means of a delivery line 400.

In one preferred embodiment, a first pressurizing means 215 maintains a first pressure within the remote precursor reservoir 210. A second pressurizing means 225 maintains a second pressure within the secondary vapor delivery system. When the first pressure is greater than the second pressure, transfer of liquid CVD precursor from the remote precursor reservoir 210 to the secondary vapor delivery system 220 through transfer line 250 is possible. First pressurizing means 215 or second pressurizing means 225 may be provided by a pressurized source of an inert gas. The liquid CVD precursor may be pyrophoric and/or water reactive. The liquid CVD precursor may be trimethyl aluminum, trimethyl gallium, triethyl gallium, diethyl zinc, or dimethyl zinc. The inert gas may be nitrogen, helium, or argon.

In another embodiment, the secondary vapor delivery system 220 may include a heating element 270 to increase temperature of the liquid CVD precursor and therefore increase the vapor concentration in the carrier gas. Heating element 270 may increase the temperature of the liquid CVD precursor to a first temperature that is greater than ambient temperature. Ambient temperature may be any temperature between 1 5° C and 35° C. Ambient temperature may be 25° C. This first temperature may be between 30° C and 50° C. This first temperature may be 40° C.

The secondary vapor delivery system 220 may be either a vaporizer, or a bubbler. If a solid CVD precursor material is used, the secondary vapor delivery system 220 may be a sublimation system. If a solid CVD precursor system is used, the solid CVD precursor may be trimethyl indium.

In one preferred embodiment, the secondary vapor delivery system 220 is a bubbler. A carrier gas is introduced into the secondary vapor delivery system by way of a second pressurizing means 225. The carrier gas may be an inert gas. The carrier gas may be helium, nitrogen, or argon. The carrier gas may be introduced at, or near, the bottom of the liquid capacity of CVD precursor in the secondary vapor delivery system. Due to the vapor pressure of the liquid CVD precursor, the carrier gas is saturated with a certain amount of the CVD precursor, which CVD precursor is the carried over with the carrier gas as it leaves the bubbler.

The bubbler technique is most useful for those precursors that have a substantial vapor pressure. The vaporizer technique is most useful for precursors with very low vapor pressures.

Once the CVD precursor is vaporized, it is introduced into delivery line 400. The delivery line 400 may contain either a carrier gas and vaporized CVD precursor, or it may contain only vaporized CVD precursor. The delivery line 400 will contain nothing in the liquid phase. In one embodiment, if the delivery line 400 is sufficiently lengthy to allow unwanted heat transfer with the environment, and thereby resulting in unwanted liquid phase presence within delivery line 400, liquid removal devices may be installed periodically along delivery line 400 to ensure that there is nothing in the liquid phase remaining in delivery line 400. Liquid removal devices may be traps, manual valves, or any such devices known to one skilled in the art. The delivery line 400 may also be warmed as needed by the use of heat tracing. The delivery line 400 may also be constructed as an insulated double-wall containment line, possibly with a vacuum in the annulus region.

The vaporized CVD precursor is then transferred from delivery line 400 to the local precursor reservoir 320. The local precursor reservoir 320 contains a heat transfer means 310. Within heat transfer means 310, the vaporized CVD precursor has a phase change into the liquid phase. Any carrier gas that may be present will not undergo this phase change, and will remain in the gas phase. The heat transfer means 310 may include a vent 330, which will allow the carrier gas, along with any other non-condensable gases, to escape. At this time, the CVD precursor has undergone a single stage of fractional distillation and the purity of the CVD precursor has been improved. Heat transfer means 310 may be any such device known to one skilled in the art. Heat transfer means 310 may be a Peltier cooler. Vent 330 may include a scrubbing means 335. Scrubbing means 335 may be a dry adsorbent.

The liquid storage region of heat transfer means 310 may function as a local precursor reservoir 320. In another embodiment, the liquid CVD precursor may be transferred from heat transfer means 310 to a discrete local precursor reservoir 320. The local precursor reservoir 320 may be an ampoule in a primary vapor delivery system 500. The local precursor reservoir 320 may feed an ampoule in a primary vapor delivery system 500.

In a preferred embodiment the local precursor reservoir 320 may have a level sensing means 325. When the liquid CVD precursor level in local precursor reservoir 320 reaches a first predetermined set point, flow control means 410 in delivery line 400 may then be opened. This will allow additional vaporized CVD precursor to flow through condenser 310, and thereby to increase the level of liquid CVD precursor in local precursor reservoir 320. Once the liquid CVD precursor level in local precursor reservoir 320 reaches a second predetermined set point, flow control means 410 in delivery line 400 may be closed.

In another embodiment, the vaporized CVD precursor is transferred from delivery line 400 to the local precursor reservoir 320. The local precursor reservoir 320 contains a heat transfer means 310. Within heat transfer means 310, the temperature of the vaporized CVD precursor is reduced to a second temperature, and has a phase change into the solid phase. One advantage for reducing the temperature of the vaporized CVD precursor to such a low second temperature is that this minimizes the loss of CVD precursor that remains entrained in the carrier gas and is vented. The lower this second temperature, the lower the unwanted loss of CVD precursor. This second temperature may be below ambient temperature. Ambient temperature is any temperature between 15° C. and 35° C., and preferably, is less than 20° C. This second temperature may be less than 16° C.

Any carrier gas that may be present will not undergo this phase change, and will remain in the gas phase. The heat transfer means 310 may include a vent 330, which will allow the carrier gas, along with any other non-condensable gases, to escape. Heat transfer means 310 may be any such device known to one skilled in the art. Heat transfer means 310 may be a Peltier cooler. Vent 330 may include a scrubbing means 335. Scrubbing means 335 may be a dry adsorbent.

The storage region of heat transfer means 310 may function as a local precursor reservoir 320. In one embodiment, heat transfer means 310 may heat the solid phase CVD precursor until it has a phase change into the liquid phase. In another embodiment, the liquid CVD precursor may be transferred from heat transfer means 310 to a discrete local precursor reservoir 320. The local precursor reservoir 320 may feed an ampoule in a primary vapor delivery system 500.

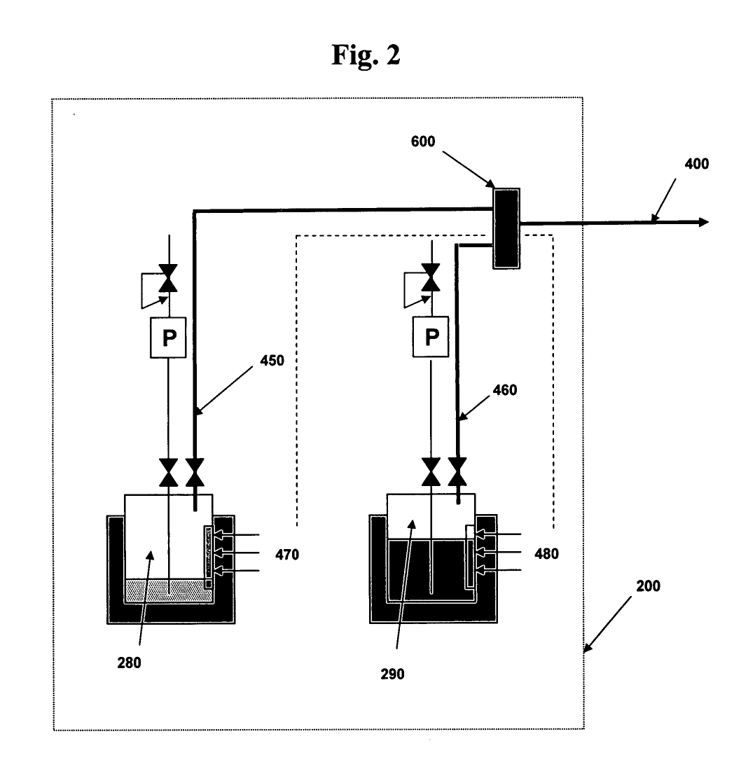

Referring to FIG. 2, in a preferred embodiment, secondary system 200 may consist of two or more secondary vapor delivery systems. A first secondary vapor delivery system 280 may feed into a first transfer line 450. The second secondary vapor delivery system 290 may feed into a second transfer line 460. The first secondary vapor delivery system 280 may comprise a first level sensing means 470, and the second secondary vapor delivery system 290 may comprise a second level sensing means 480. The first level sensing means 470 and the second level sensing means 480 may communicate with an auto-switching means 600. Should the first level sensing means 470 detect a sufficiently low liquid CVD precursor level in the first secondary vapor delivery system 280, the auto switching means 600 will switch from the first secondary vapor delivery system 280 to the second secondary vapor delivery system 290, thereby allowing an uninterrupted supply of liquid CVD precursor to the primary system 300. The auto-switching means 600 can be any such means known to one skilled in the art.

Illustrative embodiments of the invention are described above. While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

It will of course be appreciated that in the development of any such actual embodiment, numerous implementation-specific decisions must be made to achieve the developer's specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

What is claimed is:

1. A system for providing CVD precursor to a primary vapor deposition system comprising:
a) a CVD precursor remote source comprising:
i) a remote precursor reservoir; and
ii) a secondary vapor delivery system;
b) a CVD precursor local source comprising:
i) a heat transfer means; and
ii) a local precursor reservoir; and
c) a delivery line, wherein said delivery line connects said secondary vapor delivery system to said heat transfer means.

2. The system of claim 1, wherein said secondary vapor delivery system is selected from the group consisting of:
a) a vaporizer;
b) a bubbler; and
c) a solid sublimation system.

3. The system of claim 1, wherein said secondary vapor delivery system is a bubbler.

4. The system of claim 1, wherein said secondary vapor delivery system further comprises a heating element.

5. The system of claim 1, wherein said secondary vapor delivery system further comprises:
a) a first secondary vapor delivery system;
b) a second secondary vapor delivery system; and
c) an auto-switching means.

6. The system of claim 1, wherein said CVD precursor is pyrophoric, water reactive, or both.

7. The system of claim 1, wherein said CVD precursor is selected from the group consisting of:
a) trimethyl aluminum;
b) trimethyl gallium;
c) triethyl gallium;
d) diethyl zinc; and
e) dimethyl zinc.

8. The system of claim 1, wherein said delivery line transfers a carrier gas and vaporized CVD precursor, in the absence of liquid.

9. The system of claim 1, wherein said local precursor reservoir comprises an ampoule in a bubbler system.

10. The system of claim 1, wherein said local precursor reservoir feeds an ampoule in a bubbler system.

11. The system of claim 1, wherein said local precursor reservoir further comprises a level sensing means, wherein said delivery line further comprises a flow control means, and wherein said level sensing means interfaces with said flow control means.

12. A method for providing CVD precursor to a primary vapor delivery system comprising:
a) maintaining a supply of liquid CVD precursor in a remote precursor reservoir;
b) passing said liquid CVD precursor through a vaporizing means, thereby generating a vapor CVD precursor;
c) transferring said vapor CVD precursor to a heat transfer periodically through a delivery line;
d) passing said vapor CVD precursor through said heat transfer means, thereby generating a liquid CVD precursor;
e) transferring said liquid CVD precursor to a local precursor reservoir; and
f) maintaining the delivery line under vapor pressure between said periodic transfers of vapor CVD precursor.

13. The method of claim 12, further comprising a plurality of vaporizing means, and an auto-switching means, and wherein step b) further comprises the step of said auto-switching means switching from a selected one of the plurality of vaporizing means until its depletion followed by switching to a new selected one of the plurality of vaporizing means so that the transfer of vaporized CVD precursor is maintained in the delivery line.

14. The method of claim 12, wherein said vaporizing means is selected from the group consisting of:
a) a vaporizer; and
b) a bubbler.

15. The method of claim 12, wherein said vaporizing means is a bubbler.

16. The system of claim 12, wherein said delivery line transfers a carrier gas and vapor CVD precursor, in the absence of liquid.

17. The system of claim 12, wherein said local precursor reservoir comprises an ampoule in a bubbler system.

18. The system of claim 12, wherein said local precursor reservoir feeds an ampoule in a bubbler system.

19. The system of claim 12, wherein said local precursor reservoir further comprises a level sensing means, wherein said delivery line further comprises a flow control means, and wherein said level sensing means interfaces with said flow control means.

20. A method for providing CVD precursor to a primary vapor delivery system comprising:
a) maintaining a supply of liquid CVD precursor in a remote precursor reservoir;
b) passing said liquid CVD precursor through a vaporizing means, thereby generating a vapor CVD precursor;
c) transferring said vapor CVD precursor to a heat transfer means periodically through a delivery line; and
d) passing said vapor CVD precursor through said heat transfer means, thereby generating a solid CVD precursor.

21. The method of claim 20, wherein said vaporizing means is selected from the group consisting of:
a) a vaporizer; and
b) a bubbler.

22. The method of claim 20, wherein said vaporizing means is a bubbler.

23. The system of claim 20, wherein said delivery line transfers a carrier gas and vapor CVD precursor, in the absence of liquid.

24. The system of claim 20, further comprising:
a) heating said solid CVD precursor with said heat transfer means, thereby generating a liquid CVD precursor;
b) transferring said liquid CVD precursor to a local precursor reservoir; and
c) maintaining the delivery line under vapor pressure between said periodic transfers of vapor CVD precursor.

25. The system of claim 24, wherein said local precursor reservoir feeds an ampoule in a bubbler system.

26. The system of claim 24, wherein said local precursor reservoir further comprises a level sensing means, wherein said delivery line further comprises a flow control means, and wherein said level sensing means interfaces with said flow control means.
